(19) United States
(12) Patent Application Publication
(10) Pub. No.: US 2022/0084800 A1
(43) Pub. Date: Mar. 17, 2022

(54) STAGE, SUBSTRATE PROCESSING APPARATUS AND SUBSTRATE ATTRACTION METHOD

(71) Applicant: Tokyo Electron Limited, Tokyo (JP)

(72) Inventor: Takehiro TANIKAWA, Miyagi (JP)

(21) Appl. No.: 17/447,227

(22) Filed: Sep. 9, 2021

(30) Foreign Application Priority Data
Sep. 14, 2020 (JP) 2020-154150
Jun. 30, 2021 (JP) 2021-108863

(51) Int. Cl. H01J 37/32; H01L 21/683

(52) U.S. Cl. CPC H01J 37/32724; H01J 37/32128; H01J 37/32183; H01J 2237/334; H01J 37/32568; H01L 21/6833; H01J 37/32642

(57) ABSTRACT

A stage includes a base, and an electrostatic chuck disposed on the base and including n-pole electrodes therein. N is an integer of two or more. A power source is configured to apply n-phase voltages to the n-pole electrodes. The n of the n-phase corresponds to the n of the n-pole, respectively. The n-phase voltages have different phases from each other. Each of the n-phase voltages periodically switches between positive and negative. Each of the n-pole electrodes is disposed alternately in the electrostatic chuck.

### CROSS-REFERENCE TO RELATED APPLICATION

The present application is based on and claims priority to Japanese Priority Application No. 2020-154150 filed on Sep. 14, 2020, and Japanese Priority Application No. 2021-108863 filed on Jun. 30, 2021, the entire contents of which are hereby incorporated herein by reference.

### BACKGROUND OF THE INVENTION

### 1. Field of the Invention

The present disclosure relates to a stage, a substrate processing apparatus, and a substrate attraction method.

### 2. Description of the Related Art

In a processing apparatus for performing a desired process on a substrate such as an etching process, a stage that attracts the substrate is known.

Japanese Laid-Open Patent Application Publication No. 2003-332412 discloses an electrostatic chuck to which an alternating-current voltage is applied, and the alternating-current voltage has n phases, wherein n is two or more. The electrostatic chuck features electrodes to which the n-phase alternating-current voltage is applied, a stage made of an insulator that insulates an interconnection between the electrodes, and a circuit to apply the n-phase alternating-current voltage.

### SUMMARY OF THE INVENTION

In one aspect, the present disclosure provides a stage, a substrate processing apparatus and a substrate attraction method that reduce unevenness of attraction force and can reduce a cost.

According to one embodiment of the present disclosure, there is provided a stage including a base, and an electrostatic chuck disposed on the base and including n-pole electrodes therein. N is an integer of two or more. A power source is configured to apply n-phase voltages to the n-pole electrodes. The n of the n-phase corresponds to the n of the n-pole, respectively. The n-phase voltages have different phases from each other. Each of the n-phase voltages periodically switches between positive and negative. Each of the n-pole electrodes is disposed alternately in the electrostatic chuck.

### BRIEF DESCRIPTION OF THE DRAWINGS

FIG. 1 is a schematic cross-sectional view illustrating an example of a plasma processing apparatus according to an embodiment;

FIG. 2 is a plan view illustrating an example of an arrangement of electrodes in an electrostatic chuck;

FIG. 3 is a cross-sectional view illustrating an example of an arrangement of electrodes in an electrostatic chuck;

FIG. 4 is a graph illustrating an example of a three-phase alternating-current voltage that is applied to electrodes and a sum of attraction force;

FIG. 5 is a graph illustrating an example of a two-phase alternating-current voltage that is applied to electrodes and a sum of attraction force;

FIG. 6 is a plan view illustrating an example of an arrangement of electrodes of an electrostatic chuck according to a reference example;

FIG. 7 is a plan view illustrating an example of an arrangement of electrodes of an electrostatic chuck according to another reference example;

FIG. 8 is a plan view illustrating another example of an arrangement of electrodes of an electrostatic chuck; and

FIG. 9 is a graph for explaining an example of an applied voltage wave of a power source.

### DETAILED DESCRIPTION OF THE PREFERRED EMBODIMENTS

Hereinafter, embodiments of the present disclosure will be described in detail with reference to the drawings. In each drawing, the same components are indicated by the same reference numerals and overlapping descriptions may be omitted.

[Plasma Processing Apparatus]

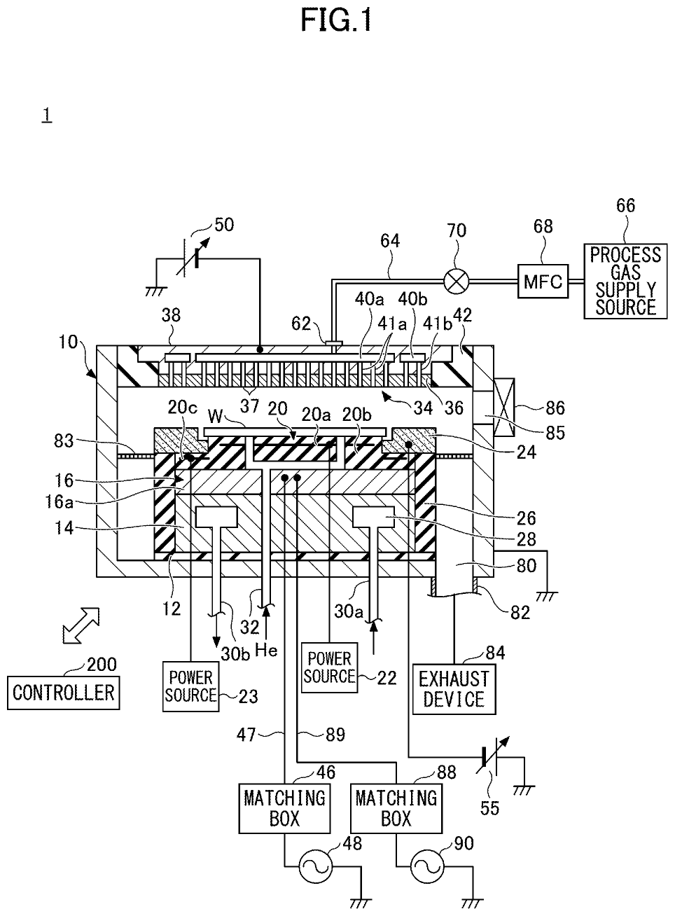

An etching processing apparatus 1 according to an embodiment will be described with reference to FIG. 1. FIG. 1 is a schematic cross-sectional view illustrating an example of a plasma processing apparatus 1 according to an embodiment. The plasma processing apparatus 1 according to the embodiment is a capactively-coupled type parallel-plate processing apparatus, and includes a chamber 10. The chamber 10 is, for example, a cylindrical vessel made of aluminum and having an anodized surface, and is grounded.

A columnar support 14 is disposed at the bottom of the chamber 10 via an insulating plate 12 made of ceramics and the like. For example, a stage 16 is disposed on the support 14. The stage 16 includes an electrostatic chuck 20 and a base 16a, and a wafer W is placed on a top face of the electrostatic chuck 20. An annular edge ring 24 made of, for example, silicon, is disposed around the wafer W. The edge ring 24 is also referred to as a focus ring. The edge ring 24 is an example of a peripheral member disposed at a peripheral portion of the stage 16. An annular insulator ring 26 made of, for example, quartz, is disposed around the base 16a and the support 14. A first electrode 20a made of a conductive film is sandwiched between insulating layers 20b inside the electrostatic chuck 20 in the middle area. The first electrode 20a is connected to a power source 22. A voltage applied to the first electrode 20a from the power source 22 causes a potential difference between the top surface of the electrostatic chuck 20 and the wafer W, which is an object to be attracted, and thus attracts the wafer W that is the object to be attracted on a wafer loading surface of the electrostatic chuck 20. Moreover, a second electrode 20c made of a conductive film is sandwiched between the insulating layers 20b inside the electrostatic chuck on the peripheral side. The second electrode 20c is connected to a power source 23. A voltage applied to the second electrode 20c from the power source 23 causes a potential difference between the top face of the electrostatic chuck 20 and the edge ring 24, which is the object to be attracted, and thus attracts the edge ring 24 that is the object to be attracted on an edge ring mounting surface of the electrostatic chuck 20. The electrostatic chuck 20 includes a heater, which may control a temperature.

For example, a ring-shaped or spiral refrigerant chamber 28 is formed inside the support 14. A refrigerant having a predetermined temperature and supplied from a chiller unit (not illustrated in the drawing), for example, cool water, passes through a pipe 30a, a refrigerant chamber 28 and a pipe 30b, and returns to the chiller unit. The refrigerant circulates in such a path, and thus the temperature of the refrigerant controls the temperature of the wafer W. Furthermore, a heat transfer gas supplied from a heat transfer gas supply mechanism (not illustrated in the drawing), for example, He (helium) gas, is supplied to a gap between the surface of the electrostatic chuck 20 and the back surface of the edge ring 24 via a gas supply line. Moreover, by controlling a pressure of He gas supplied to the gap between the surface of the electrostatic chuck 20 and the back surface of the object to be attracted (wafer W and edge ring 24), a heat transfer property between the electrostatic chuck 20 and the object to be attracted (wafer W and edge ring 24) may be controlled, and the temperature of the object to be attracted (wafer W and edge ring 24) may be controlled.

An upper electrode 34 is disposed in a ceiling of the chamber while facing the stage 16. A space between the upper electrode 34 and the stage 16 forms a plasma processing space. The upper electrode 34 closes an opening of the chamber 10 via a blocking member 42 made of an insulator. The upper electrode 34 includes an electrode plate 36 and an electrode support 38. The electrode plate 36 includes many gas discharge holes 37 formed in a face facing the stage 16, and is formed of silicon-containing material such as silicon or SiC. The electrode support 38 detachably supports the electrode plate 36, and is formed of a conductive material, for example, aluminum having an anodized surface. Many gas flowing holes 41a and 41b extend downward from gas diffusion chambers 40a and 40b and are in communication with the gas discharge holes 37.

A gas introduction inlet 62 is connected to a process gas supply source 66 via a gas supply tube 64. The gas supply tube 64 is provided with a mass flow controller (MFC) 68 and opening/closing valve 70 in this order from the process gas supply source 66 disposed upstream. The process gas supply source 66 supplies a process gas, and the mass flow controller 68 and the open and close valve 70 control a flow rate of the process gas and an open and close, and the process gas passes the gas diffusion chambers 40a and 40b, the gas flowing holes 41a and 41b via the gas supply tube 64, and is discharged from the gas discharge holes 37 in a shower-like manner.

The plasma processing apparatus 1 includes a first radio frequency power source 90 and a second radio frequency power source 48. The first radio frequency power source 90 is a power source to generate a first radio frequency (which is hereinafter referred to as “HF power”). The first radio frequency power has a frequency appropriate for plasma generation. The frequency of the first radio frequency power is, for example, in a range of 27 MHz to 100 MHz. The first radio frequency power source 90 is connected to the base 16a via a matching box 88 and a power source line 89. The matching box 88 includes a circuit to match output impedance of the first radio frequency power source 90 with impedance on a loading side (on the base 16a side). The first radio frequency power source 90 may be connected to the upper electrode 34 via the matching box 88.

The second radio frequency power source 48 is a power source that generates the second radio frequency power (hereinafter referred to as “LF power”). The second radio frequency power has a frequency lower than the frequency of the first radio frequency power. If the second radio frequency power is used in conjunction with the first radio frequency power, the second radio frequency power is used as the radio frequency power for bias to attract ions onto the wafer W. The frequency of the second radio frequency power is, for example, in the range of 400 kHz to 13.56 MHz. The second radio frequency power source 48 is connected to the base 16a via a matching box 46 and a power supply line 47. The matching box 46 includes a circuit for matching the output impedance of the second radio frequency power source 48 to the impedance on the load side (base 16a side). The direct-current pulse may be used as power for bias to draw ions to the wafer W. In this case, the plasma processing apparatus 1 includes a direct-current pulse power source (not illustrated in the drawing) instead of the second radio frequency power source 48. The direct-current pulse power source is connected to the base 16a via the power supply line 47. Alternatively, a composite wave in which a plurality of input voltages, such as a direct-current pulse (rectangular wave) or a triangular wave, are combined may be used as the power for bias to draw ions to the wafer W. In this case, the plasma processing apparatus 1 has a power source (not illustrated in the drawing) that outputs a composite wave in place of the second radio frequency power source 48. The power source for outputting the composite wave is connected to the base 16a via the power supply line 47.

Plasma may be generated using the second radio frequency power without using the first radio frequency power, i.e., using only a single radio frequency power. In this case, the frequency of the second radio frequency power may be greater than 13.56 MHz, for example, 40 MHz. The plasma processing apparatus 1 may not include the first radio frequency power source 90 and the matching box 88. This structure causes the stage 16 also to serve as a lower electrode. Also, the upper electrode 34 serves as a showerhead for supplying a gas.

A second variable power source 50 is connected to the upper electrode 34 and applies a direct-current voltage to the upper electrode 34. A first variable power source 55 is connected to the edge ring 24 and applies a direct-current voltage to the edge ring 24. The thickness of the sheath on the edge ring 24 is controlled by applying a predetermined direct-current voltage to the edge ring 24 from the first variable power source 55 depending on the amount of consumption of the edge ring 24. This eliminates difference in level between the sheath on the edge ring 24 and the sheath on the wafer W, prevents the irradiation angle of ions from becoming oblique at the edge of the wafer W, and avoids the occurrence of tilting in which the shape of the recess formed on the wafer W becomes oblique.

An exhaust device 84 is connected to an exhaust tube 82. The exhaust device 84 includes a vacuum pump, such as a turbomolecular pump, which evacuates the chamber 10 through the exhaust tube 82 from an exhaust port 80 formed at the bottom of the chamber 10 to reduce the pressure in the chamber 10 to a desired degree of vacuum. The exhaust device 84 also controls the pressure in the chamber 10 to a constant value while using a value of a pressure gauge (not illustrated in the drawing) to measure the pressure in the chamber 10. A transfer port 85 is disposed on the side wall of the chamber 10. The wafer W is transported in and out of the transfer port 85 by opening and closing a gate valve 86.

An annular baffle plate 83 is disposed between the insulator ring 26 and the side wall of the chamber 10. The baffle plate 83 includes a plurality of through-holes, is formed of aluminum, and has a surface coated with a ceramic such as Y₂O₃.

When performing a predetermined plasma process such as a plasma etching process, in the plasma processing apparatus 1 of such a configuration, the gate valve 86 is opened, and the wafer W is carried into the chamber 10 via the transfer port 85, placed on the wafer loading surface of the electrostatic chuck 20, and then the gate valve 86 is closed. The edge ring 24 is disposed on the edge ring mounting surface of the electrostatic chuck 20. A process gas is supplied into the chamber 10, and the exhaust device 84 evacuates the chamber 10.

A first radio frequency power and a second radio frequency power are supplied to the stage 16. The power source 22 then applies a voltage to the first electrode 20a of the electrostatic chuck 20, thereby attracting the wafer W on the wafer loading surface of the electrostatic chuck 20. The power source 23 also applies a voltage to the second electrode 20c of the electrostatic chuck 20, thereby attracting the edge ring 24 on the edge ring mounting surface of the electrostatic chuck 20. A direct-current voltage may be applied to the upper electrode 34 from the second variable power source 50.

A plasma process such as etching, is performed on the surface to be processed of the wafer W by radicals or ions in the plasma generated in the plasma processing space.

The plasma processing apparatus 1 includes a controller 200 for controlling the operation of the entire apparatus. A CPU disposed in the controller 200 performs a desired plasma process such as etching, according to a recipe stored in a memory such as ROM and RAM. The recipe may specify process time, a pressure (gas evacuation), first and second radio frequency powers and voltages, and various gas flows, which are control information of the apparatus corresponding to process conditions. The recipe may also specify a temperature in the chamber (top electrode temperature, chamber sidewall temperature, wafer W temperature, electrostatic chuck temperature, and the like), a temperature of the refrigerant output from the chiller, and the like. The recipe representing these programs and processing conditions may be stored in a hard disk or a semiconductor memory. Also, the recipe may be set in a predetermined position and read out in a portable computer-readable storage medium such as a CD-ROM and a DVD.

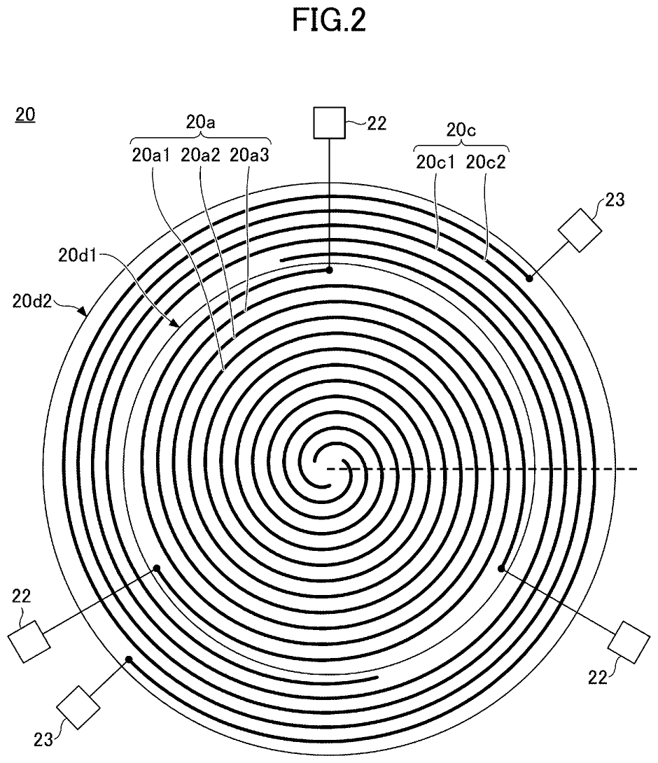

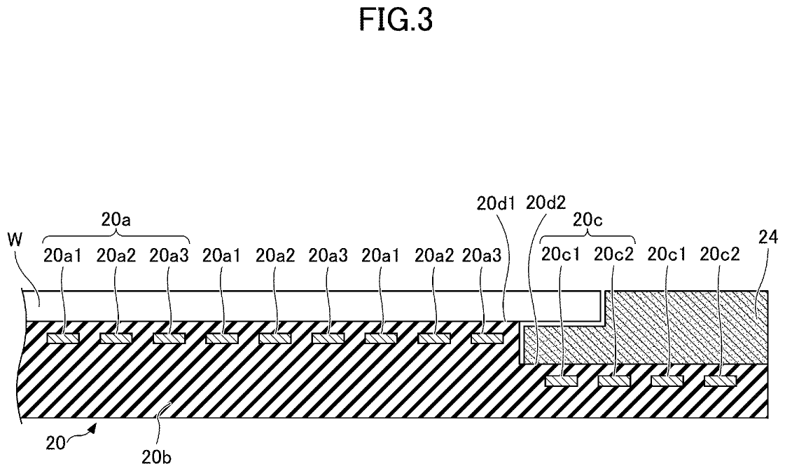

Next, an electrode arrangement of the electrostatic chuck 20 on the stage 16 will be further described with reference to FIGS. 2 and 3. FIG. 2 is a plan view illustrating an example of an arrangement of electrodes 20a and 20c of the electrostatic chuck 20. FIG. 3 is a cross-sectional view illustrating an example of an arrangement of the electrodes 20a and 20c of the electrostatic chuck 20. The electrostatic chuck 20 has a wafer loading surface 20d1 on which a wafer W is loaded and an edge ring mounting surface 20d2 on which an edge ring 24 is loaded. FIG. 3 is a cross-sectional view, for example, cut at the position of a broken line in FIG. 2.

As illustrated in FIGS. 2 and 3, the first electrode 20a in a wafer loading surface 20d1 includes two or more of n-pole (n is an integer of two or more) electrodes. In the example of the electrostatic chuck 20 illustrated in FIGS. 2 and 3, the first electrode 20a is a three-pole electrode including electrodes 20a1, 20a2, and 20a3.

The electrode 20a1 is arranged in a spiral manner around the central axis of the electrostatic chuck 20. In other words, the electrode 20a1 is formed from the central area to the outer circumferential side of the wafer loading surface 20d1 and is spirally formed such that the rotation radius increases as the rotation angle increases. That is, the electrode 20a1 is disposed throughout the circumferential direction around the central axis of the electrostatic chuck 20 and is disposed from the center of the wafer loading surface 20d1 to the periphery (the peripheral portion). The electrodes 20a2 and 20a3 are similarly arranged in a spiral manner.

The electrodes 20a1, 20a2, and 20a3 have an area ratio of one. That is, the electrodes 20a1, 20a2, and 20a3 are equally formed in area.

The electrodes 20a1, 20a2, and 20a3 are arranged coaxially with respect to the central axis of the electrostatic chuck 20 and are arranged with rotational symmetry. That is, the first electrode 20a consisting of the three electrodes has a rotational symmetry of 120 degrees. When the electrode 20a1 is rotated 120 degrees about the central axis of the electrostatic chuck 20 as the rotation axis, the electrode 20a1 coincides with the electrode 20a2. When the electrode 20a1 is rotated 240 degrees, the electrode 20a1 coincides with the electrode 20a3.

Further, as illustrated in FIG. 3, the electrode 20a3 is disposed adjacent to the radially inner side of the electrode 20a1, and the electrode 20a2 is disposed adjacent to the radially outer side of the electrode 20a1. The electrode 20a1 is disposed adjacent to the radially inner side of the electrode 20a2, and the electrode 20a3 is disposed adjacent to the radially outer side of the electrode 20a2. The electrode 20a2 is disposed adjacent to the inside of the electrode 20a3 in a radial direction, and an electrode 20a1 is disposed adjacent to the outside of the electrode 20a3 in a radial direction.

The power source 22 is connected to each of the electrodes 20a1, 20a2, and 20a3. The power source 22 applies two or more of n-phase alternating-current voltages that differ in phase from each other to the first electrode 20a including two or more of n-pole (n is an integer of two or more) electrodes. In the example of the electrostatic chuck 20 illustrated in FIG. 2, the power source 22 applies three-phase alternating-current voltages that differ in phase from each other to the three-pole electrodes 20a1, 20a2, and 20a3, respectively.

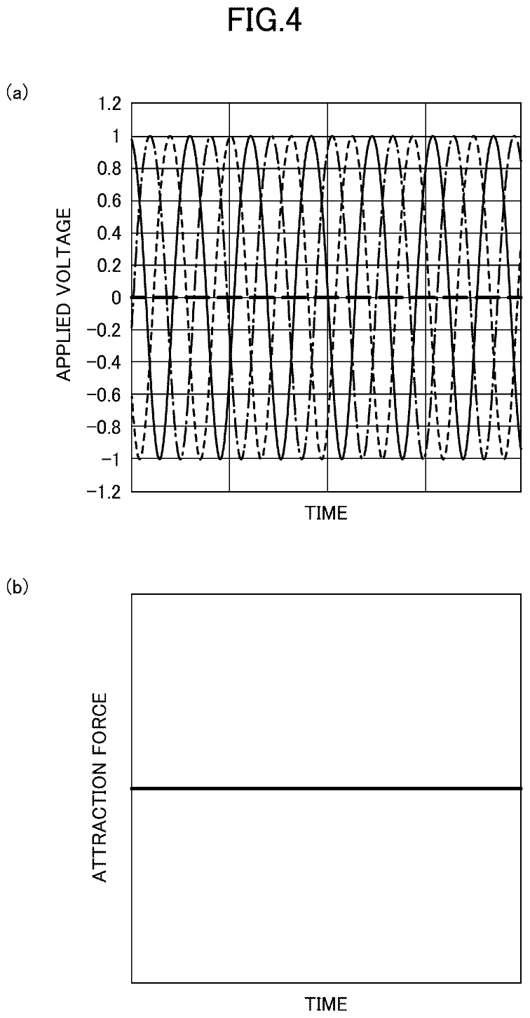

Next, a three-phase alternating-current voltage applied to the first electrode 20a including three poles (electrodes 20a1, 20a2, and 20a3) will be described with reference to FIG. 4(a). FIG. 4(a) is a graph illustrating an example of three-phase alternating-current voltages applied to electrodes 20a1, 20a2, and 20a3. The vertical axis represents an applied voltage, and the horizontal axis represents time. An example of an alternating-current voltage applied to the electrode 20a1 is shown in a solid line graph, an example of an alternating-current voltage applied to the electrode 20a2 is shown in a dashed-dotted line graph, and an example of an alternating current voltage applied to the electrode 20a3 is shown in a broken line graph. An amplitude of the applied voltage is normalized to 1.

The power source 22 applies alternating-current voltages having the same maximum amplitude, the same frequency, and different phases to electrode 20a1, 20a2, and 20a3 each. For example, the phase difference of the alternating-current voltages applied to the electrodes 20a1, 20a2, and 20a3 is set to 120°.

The attraction force of the wafer W when the three-phase alternating-current voltage illustrated in FIG. 4(a) is applied to the first electrode 20a (electrodes 20a1, 20a2, and 20a3) is described with reference to FIG. 4(b). FIG. 4(b) is a graph illustrating an example of the sum of the attraction forces of the wafer W when three-phase alternating-current voltages are applied to the electrodes 20a1, 20a2, and 20a3. The vertical axis represents the sum of the attraction forces, and the horizontal axis represents time. As illustrated in FIG. 4(b), the attraction force at which the stage 16 attracts the wafer W can be made constant.

As illustrated in FIGS. 2 and 3, the second electrode 20c in the edge ring mounting surface 20d2 includes two or more of n (n is an integer of two or more) electrodes. In the example of the electrostatic chuck 20 illustrated in FIGS. 2 and 3, the second electrode 20c is a bipolar electrode including electrodes 20c1 and 20c2.

The electrode 20c1 is arranged in a spiral manner around the central axis of the electrostatic chuck 20. In other words, the electrode 20c1 is formed from the inner periphery of the edge ring mounting surface 20d2 to the outer periphery of the edge ring mounting surface 20d2, and is formed in a spiral shape such that the rotation radius increases as the rotation angle increases. That is, the electrode 20c1 is disposed throughout the circumferential direction around the central axis of the electrostatic chuck 20 and is disposed from the inner periphery of the edge ring mounting surface 20d2 to the outer periphery of the edge ring mounting surface 20d2. The electrode 20c2 is similarly arranged in a spiral manner.

The area ratio between the electrodes 20c1 and 20c2 is one. That is, the electrodes 20c1 and 20c2 are formed to be of equal area.

The electrodes 20c1 and 20c2 are arranged coaxially with respect to the central axis of the electrostatic chuck 20 and are symmetrically arranged in a rotational direction. That is, the second electrode 20c consisting of two electrodes has a rotational symmetry of 180 degrees. When the electrode 20c1 is rotated 180° about the central axis of the electrostatic chuck 20, the electrode 20c2 coincides with the electrodes 20c1.

Further, as illustrated in FIG. 3, the electrode 20c2 is disposed adjacent to the radially inner side of the electrode 20c1, and the electrode 20c2 is disposed adjacent to the radially outer side of the electrode 20c1. The electrode 20c1 is disposed adjacent to the radially inner side of the electrode 20c2, and the electrode 20c1 is disposed adjacent to the radially outer side of the electrode 20c2.

The power source 23 is connected to the electrodes 20c1 and 20c2. The power source 23 applies two or more of n-phase alternating-current voltages that differ in phase from each other to the second electrode 20c including two or more of n-pole electrodes. In the example of the electrostatic chuck 20 illustrated in FIG. 2, the power source 23 applies two-phase alternating-current voltages that differ in phase from each other to the two-pole electrodes 20c1 and 20c2.

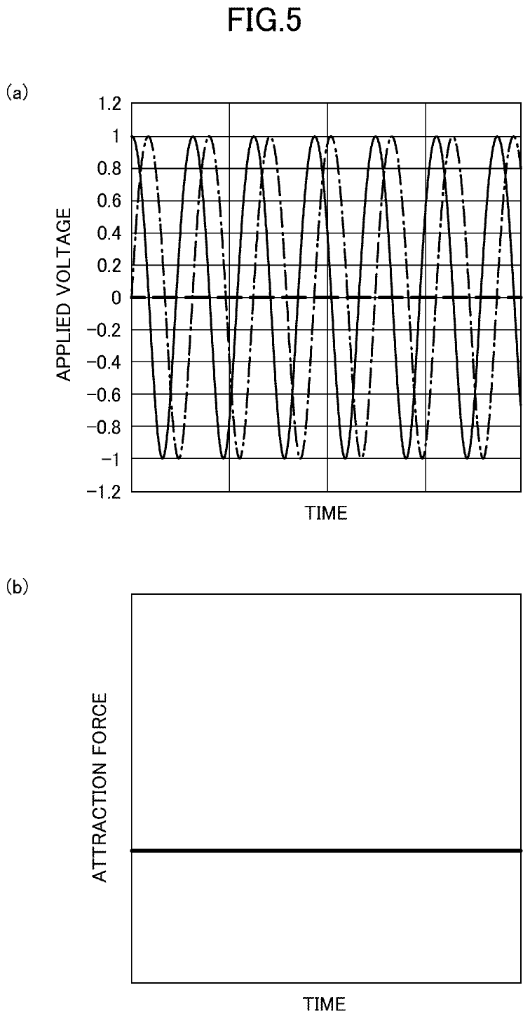

Next, a two-phase alternating-current voltage applied to the second electrode 20c having two electrodes (electrodes 20c1 and 20c2) will be described with reference to FIG. 5(a). FIG. 5(a) is a graph illustrating an example of a two-phase alternating-current voltage applied to the electrodes 20c1 and 20c2. The vertical axis represents an applied voltage, and the horizontal axis represents time. An example of an alternating-current voltage applied to the electrode 20c1 is shown with a solid line graph, and an example of an alternating-current voltage applied to the electrode 20c2 is shown with a dashed-dotted line graph. The amplitude of the applied voltage is normalized to 1.

The power source 23 applies alternating-current voltages having the same maximum amplitude, the same frequency, and different phases from each other to the electrodes 20c1 and 20c2 of the second electrode 20c, respectively. For example, the phase difference of the alternating-current voltages applied to the electrodes 20c1 and 20c2 is set to 90°.

The attraction force of the edge ring 24 when a two-phase alternating-current voltage shown in FIG. 5(a) is applied to the second electrode 20c (20c1, 20c2) will be described with reference to FIG. 5(b). FIG. 5(b) is a graph illustrating an example of the sum of attraction forces of the edge ring 24 when a two-phase alternating-current voltage is applied to the electrodes 20c1 and 20c2. The vertical axis represents the sum of the attraction forces, and the horizontal axis represents time. As shown in FIG. 5(b), even when the number of poles of the second electrode 20c is two, the attraction force by the stage 16 for attracting the edge ring 24 can be made constant.

Further, in FIGS. 2 to 4, although the number of poles of the first electrode 20a is three and the number of poles of the second electrode 20c is two, the numbers are not limited to the embodiment. The number of poles of the first electrode 20a and the number of poles of the second electrode 20c may be two or more. The poles of the first electrode 20a and the poles of the second electrode 20c may be the same or different.

Here, in the n-pole electrode, the n-phase alternating-current voltage is given by the following equation (1) when A represents an amplitude, and ω represents a period. N is an individual integer corresponding to each electrode of n or less.

A sin(ωt+N/n×360°) (1)

In addition, the phase difference between one electrode (e.g., electrode 20a2) and the other electrode on the inner peripheral side (e.g., electrode 20a1) is (1/n×360°), and the phase difference between the one electrode (e.g., electrode 20a2) and the other electrode on the outer peripheral side (e.g., electrode 20a3) is (1/n×360°). Therefore, the potential difference between adjacent electrodes can be reduced. Thus, the short circuit between the electrodes can be reduced.

In other words, the space between the electrodes can be narrowed and the area (radial width) of the electrodes can be increased. This can increase the percentage of the first electrode 20a in the wafer loading surface 20d1. Here, the attraction force is generated at the position where the electrode is formed, and no attraction force is generated in the insulating region between the electrodes. According to the electrostatic chuck 20, by increasing the electrode area, the attraction force of the wafer W can be improved. In addition, uniformity of the attraction force across the surface can be improved. Although an example of the first electrode 20a for attracting the wafer W has been described, the same applies to the second electrode 20c for attracting the edge ring 24.

In addition, it is preferable to use an alternating-current voltage having six or more phases and an electrode having six or more poles. For example, in the case of a six-phase alternating-current voltage, the phase difference between adjacent electrodes is 60 degrees, and the potential difference between adjacent electrodes becomes at most the amplitude A. Therefore, a short circuit between the electrodes can be reduced. In addition, by narrowing the space between the electrodes and widening the area (radial width) of the electrodes, the attraction force can be improved and the uniformity of the attraction force across the surface can be improved. These effects can be enhanced as the number of poles (the number of phases of the alternating-current voltage) of the electrode increases.

In addition, because the electrodes 20a1, 20a2, and 20a3 are formed in a spiral shape, the electrostatic chuck 20 can reduce the unevenness of the attraction force to the wafer W in the circumferential direction.

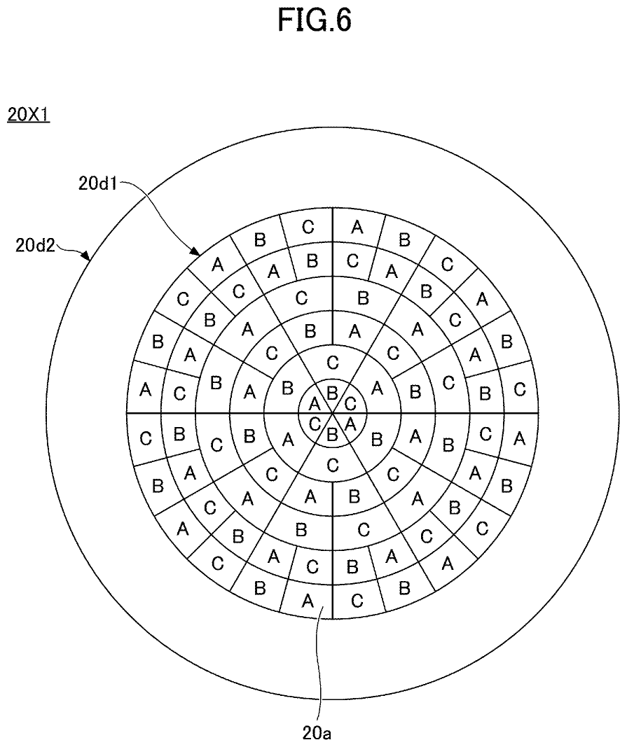

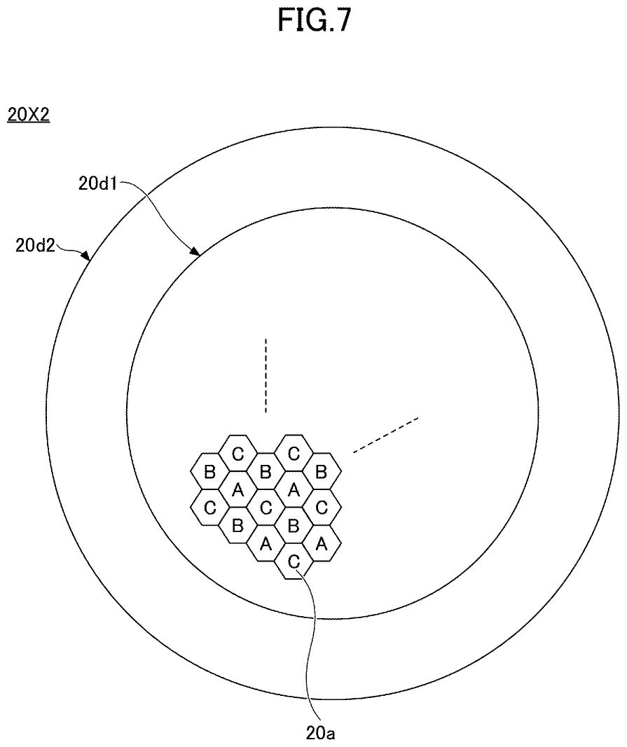

Here, an electrostatic chuck 20 according to a reference example will be described with reference to FIGS. 6 and 7. FIG. 6 is a plan view illustrating an example of an arrangement of electrostatic chuck electrodes 20X1 according to the reference example. In the arrangement of the electrodes illustrated in FIG. 6, the three-pole electrodes illustrated in A, B, and C are alternately disposed in compartments extending in radial and circumferential directions. This arrangement has circumferential symmetry. FIG. 7 is an example of a plan view illustrating an example of an electrode 20X2 arrangement of an electrostatic chuck according to another reference example. In the electrode arrangement example illustrated in FIG. 7, the three-pole electrodes represented by A, B, and C are alternately arranged in a hexagonal shape. This arrangement has circumferential symmetry.

However, in the arrangement example of the electrodes illustrated in FIGS. 6 and 7, the electrodes corresponding to the first electrode are divided into multiple electrodes; the wiring between each electrode and the power source 22 branches into multiple wirings; and the connection points between each electrode and the power source 22 are also multiple connection points.

In contrast, in the electrostatic chuck 20 illustrated in FIG. 2, the electrodes 20a1, 20a2, and 20a3 formed in the spiral manner are connected to the power source 22 at one point each. This can reduce the manufacturing cost of the electrostatic chuck 20.

As illustrated in FIG. 2, the electrostatic chuck 20 has been described such that the electrodes 20a1, 20a2, and 20a3 of the first electrode 20a for attracting the wafer W are arranged in a spiral manner. However, the present disclosure is not limited thereto. The first electrode 20a may include two or more of n-pole electrodes; the n-pole electrodes may be alternately disposed; and the connection between the n-pole electrodes and the power source 22 may be one point each.

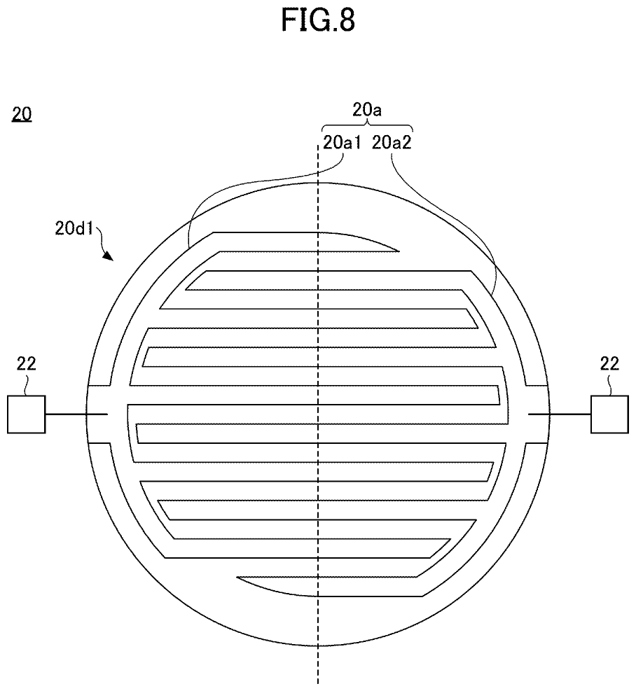

Another example of an electrode arrangement of an electrostatic chuck 20 will be described with reference to FIG. 8. FIG. 8 is a plan view illustrating another example of the arrangement of electrodes of the electrostatic chuck 20. The first electrode 20a may be formed into a comb tooth shape. That is, the first electrode 20a includes an electrode 20a1 and an electrode 20a2. The electrode 20a1 has an arc-shaped base portion connected to the power source 22 and multiple branch portions (tooth portions) branching from the base portion and extending parallel to each other. Similarly, the electrode 20a2 includes an arc-shaped base portion connected to the power source 22 and a plurality of branch portions (tooth portions) branching from the base portion and extending parallel to each other. The branch portions of the electrodes 20a1 and 20a2 are alternately arranged, that is, a branch portion of the electrode 20a2 is arranged between a branch portion of the electrode 20a1 and another branch portion of the electrode 20a1. A branch portion of the electrode 20a1 is disposed between a branch portion of the electrode 20a2 and another branch portion of the electrode 20a2. When viewing the cross-section of the electrostatic chuck 20 cut at the broken line position of FIG. 8, the branch portion of the electrode 20a1 and the branch portion of the electrode 20a2 are alternately disposed. Further, the connections between the electrodes 20a1, 20a2 and the power source 22 are one point each.

Thus, the electrostatic chuck 20 having the comb-shaped electrodes 20a1 and 20a2 illustrated in FIG. 8 can reduce the unevenness of the attraction force and the manufacturing cost of the electrostatic chuck 20, similar to the electrostatic chuck 20 including the spiral electrodes 20a1 to 20a3 illustrated in FIG. 2.

FIG. 8 illustrates the case of the electrode 20a1 attracting the wafer W. Also, in the electrode 20a2 attracting the edge ring 24, the electrode including two or more of n-poles may be configured so that the n-poles are alternately disposed, and the connections between the n-pole electrodes and the power source 22 are one point each. For example, the electrode 20a2 may be formed into a comb tooth shape. In addition, the shapes of the electrodes 20a1 and 20a2 may be different. For example, one of the electrodes 20a1 and 20a2 may be formed into a spiral shape, and the other may be formed into a comb tooth shape.

Further, although the power sources 22 and 23 have been described as power sources to apply alternating-current voltages, the present disclosure is not limited thereto. The power sources 22 and 23 may apply alternating-current voltages that periodically switch between positive and negative voltages. In other words, the power sources 22 and 23 may periodically apply alternating-current voltages that repeat the maximum value and the minimum value of the amplitude. In other words, the power sources 22 and 23 may apply alternating-current voltages that repeatedly increase and decrease.

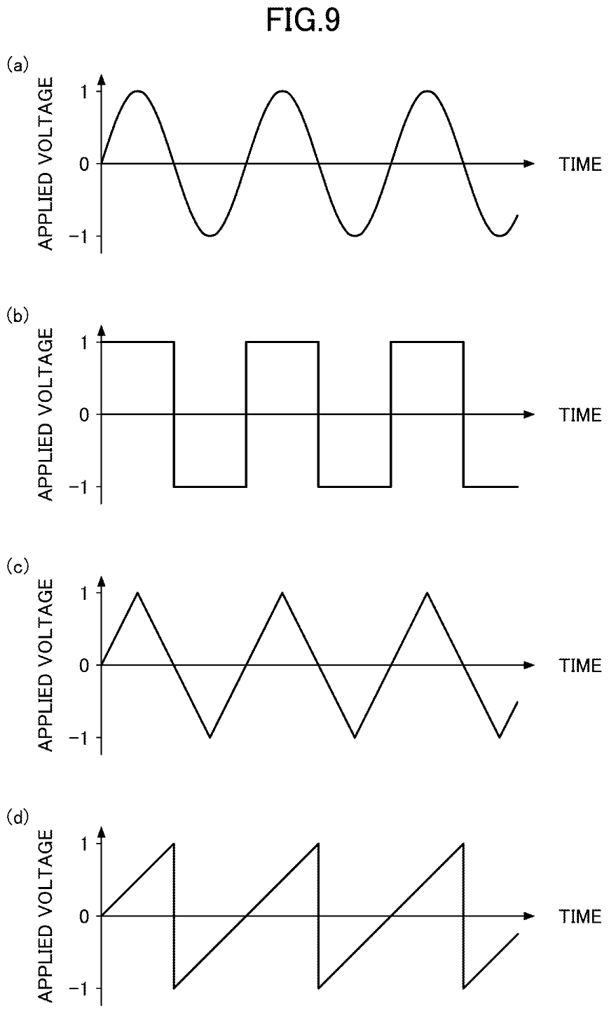

An example of the applied voltage waveform of the power source will be described with reference to FIG. 9. FIG. 9 illustrates graphs illustrating examples of applied voltage waveforms of a power source. In FIG. 9, the horizontal axis represents time, and the vertical axis represents the applied voltage. The amplitude of the applied voltage is normalized to 1.

As illustrated in FIG. 9(a) (see also FIGS. 4(a) and 5(a)), each of the power sources 22 and 23 may apply a sinusoidal voltage.

Also, as illustrated in FIG. 9(b), each of the power sources 22 and 23 may apply a voltage of a rectangular wave. The applied voltage of the rectangular wave periodically repeats the maximum applied voltage being maintained for a predetermined period of time; and then the voltage drops sharply, and the minimum applied voltage is maintained for a predetermined period of time; and then the voltage rises sharply. This cause the rectangular wave applied voltage to periodically change between positive and negative voltages.

Also, as illustrated in FIG. 9(c), each of the power sources 22 and 23 may apply a triangular wave voltage. The applied voltage of the triangular wave periodically increases from the minimum value to the maximum value, and decreases from the maximum value to the minimum value. This results in periodic changes in the applied voltage of the triangular wave.

Further, as illustrated in FIG. 9(d), each of the power sources 22 and 23 may apply a sawtooth voltage. The applied voltage of the sawtooth wave periodically repeats a gradual increase in applied voltage from the minimum value to the maximum value and a sharp decrease in applied voltage from the maximum value to the minimum value. As a result, the applied voltage of the sawtooth wave periodically changes between positive and negative voltages.

Also, although not illustrated, the power sources 22 and 23 may apply a reverse sawtooth voltage. The reverse sawtooth applied voltage periodically repeats a sharp increase in applied voltage from the minimum to the maximum and a gradual decrease in applied voltage from the maximum to the minimum. This results in periodic changes in positive and negative voltages of the reverse sawtooth wave.

Also, although not illustrated, each of the power sources 22 and 23 may apply a pseudo-sinusoidal voltage. The applied voltage of the pseudo-sinusoidal wave periodically drops in multiple stages after maintaining the maximum applied voltage for a predetermined period of time, and increases in multiple stages after maintaining the minimum applied voltage for a predetermined period of time. This causes the applied voltage of the pseudo-sinusoidal wave to periodically switch between positive and negative voltages.

The waveforms of the power sources 22 and 23 are preferably equal in period of positive and negative voltages and amplitude in the periodically switching voltages, for example, as illustrated in FIGS. 4, 5, and 9(a) to (d).

Although the embodiment of the plasma processing apparatus 1 has been described, the present disclosure is not limited to the above-described embodiment, and various modifications and alternations can be made within the scope of the spirit of the present disclosure described in the claims.

When an electrode is a two-pole electrode, the alternating-current voltage illustrated in FIG. 4 is applied. However, this is not limited thereto. The reverse phase voltage may be applied to the electrode. Thus, attraction by Johnson Rahbek force can be achieved.

Thus, as discussed above, an embodiment of the present disclosure can provide a stage, a plasma processing apparatus, and a substrate attraction method that can inhibit unevenness of attraction force of a stage and can reduce a manufacturing cost.

All examples recited herein are intended for pedagogical purposes to aid the reader in understanding the disclosure and the concepts contributed by the inventor to furthering the art, and are to be construed as being without limitation to such specifically recited examples and conditions, nor does the organization of such examples in the specification relate to a showing of the superiority or inferiority of the disclosure. Although the embodiments of the present disclosure have been described in detail, it should be understood that various changes, substitutions, and alterations could be made hereto without departing from the spirit and scope of the disclosure.

What is claimed is:

1. A stage, comprising:
a base;
an electrostatic chuck disposed on the base and including n-pole (n is an integer of two or more) electrodes therein; and
a power source configured to apply n-phase voltages to the n-pole electrodes, the n of the n-phase corresponding to the n of the n-pole, respectively, the n-phase voltages having different phases from each other, and each of the n-phase voltages periodically switching between positive and negative,
wherein each of the n-pole electrodes is disposed alternately in the electrostatic chuck.

2. The stage as claimed in claim 1, wherein the power source is configured to apply an alternating-current voltage.

3. The stage as claimed in claim 1, wherein the power source applies one of a rectangular wave, a triangular wave, and a sawtooth wave.

4. The stage as claimed in claim 1, wherein the n-pole electrodes are disposed in a spiral manner.

5. The stage as claimed in claim 1, wherein the n-pole electrodes include a base portion connected to the power source, and branch portions branching from the base portion, and
wherein the branch portions of the n-pole electrodes are disposed alternately.

6. The stage as claimed in claim 1, wherein the n-pole electrodes are formed to be of equal area.

7. The stage as claimed in claim 1, wherein the n-pole electrodes are rotationally symmetrical.

8. The stage as claimed in claim 1, wherein the n-phase alternating-current voltages have a phase difference represented by 1/n×360°.

9. The stage as claimed in claim 1, wherein the n-pole electrodes have six poles or more.

10. The stage as claimed in claim 1, wherein the electrostatic chuck is configured to attract a substrate.

11. The stage as claimed in claim 1, wherein the electrostatic chuck is configured to attract an annular member disposed at an outer periphery of a substrate.

12. A substrate processing apparatus, comprising:
a chamber;
a stage disposed in the chamber;
a base included in the stage;
an electrostatic chuck disposed on the base and including n-pole (n is an integer of two or more) electrodes therein; and
a power source configured to apply n-phase voltages to the n-pole electrodes, the n of the n-phase corresponding to the n of the n-pole, respectively, the n-phase voltages having different phases from each other, and each of the n-phase voltages periodically switching between positive and negative,
wherein each of the n-pole electrodes is disposed alternately in the electrostatic chuck.

13. A substrate attraction method for attracting at least one of a substrate and an edge ring on an electrostatic chuck including n-pole (n is an integer of two or more) electrodes alternately disposed, comprising a step of:
applying n-phase voltages having different phases from each other to the n-pole electrodes, the n of the n-phase corresponding to the n of the n-pole, respectively, each of the n-phase voltages periodically switching between positive and negative.

14. The attraction method as claimed in claim 13, wherein the n-phase voltages are n-phase alternating-current voltages, and the phase difference of the n-phase alternating-current voltages is represented by 1/n×360°.
